(19) United States
(12) Patent Application Publication
(10) Pub. No.: US 2026/0215290 A1
(43) Pub. Date: Jul. 23, 2026

(54) SEMICONDUCTOR PACKAGE STRUCTURE AND METHOD OF FORMING THE SAME

(71) Applicant: Taiwan Semiconductor Manufacturing Company, Ltd., Hsinchu (TW)

(72) Inventors: Shu-Huai HSU, Keelung City (TW); Tzu-Shiun SHEU, Hsinchu (TW); Yung-Ping CHIANG, Zhubei City (TW)

(21) Appl. No.: 19/033,905

(22) Filed: Jan. 22, 2025

(51) Int. Cl. H01L 23/00; H01L 21/48; H01L 23/13

(52) U.S. Cl. CPC H10W 70/05; H10W 70/68; H10W 72/01271; H10W 72/072; H10W 72/07211; H10W 72/073; H10W 74/15; H10W 90/724; H10W 90/734

(57) ABSTRACT

A semiconductor package structure and a method of forming the same are provided. The semiconductor package structure includes a substrate. An integrated circuit (IC) die is bonded to the surface of the substrate through electrical connectors. A trench is formed on the surface of the substrate and near a sidewall of the IC die.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules (MCM), for example, or in other types of packaging.

One smaller type of packaging for semiconductors is a flip-chip chip scale package (FcCSP), in which a semiconductor die is placed upside-down on a substrate and bonded to the substrate through solder bonding. The substrate has wiring routed to connect exposed conductive features on the die to contact pads on the substrate that have a larger footprint. An array of solder balls is formed on the opposite side of the substrate and is used to electrically connect the packaged die to another device or system.

Although existing package structures and methods for fabricating package structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A to 1D illustrate cross-sectional views of various stages in the formation of a semiconductor package, in accordance with some embodiments.

FIGS. 2A to 2D illustrate various views of a semiconductor package having trenches in the substrate, in accordance with some embodiments.

FIGS. 3A and 3B illustrate trenches with different cross-sectional shapes in the substrate, in accordance with some embodiments.

FIG. 4 illustrates trenches in the substrate extending below an integrated circuit (IC) die, in accordance with some embodiments.

FIGS. 5A to 5C illustrate trenches with different arrangements in plan view, in accordance with some embodiments.

FIG. 6 illustrates a plan view of a semiconductor package that includes additional trenches in the substrate extending beneath IC dies, in accordance with some embodiments.

FIG. 7 illustrates a process flow for forming a semiconductor package, in accordance with some embodiments.

FIG. 8 illustrates a cross-sectional view of a semiconductor package having trenches in an interposer substrate, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The structure may be otherwise oriented (rotated 90 degrees or at other orientations) and the spatially relative descriptors used herein may likewise be interpreted accordingly.

A semiconductor package (structure) and the method for forming the same are provided in accordance with various embodiments. The semiconductor package may include one or more trenches located in a substrate and near the edge(s) of an integrated circuit (IC) die mounted on the substrate to promote the flow of cleaning solvent into the gap between the IC die and the substrate during flux cleaning. This improves flux cleaning efficiency, thereby reducing flux residue and preventing void formation in the underfill element. Accordingly, the reliability of the package structure is improved. The embodiments discussed herein provide examples to enable making or using the subject matter of this disclosure, and a person having ordinary skill in the art will readily understand that modifications can be made while remaining within the contemplated scope of different embodiments. Throughout the various views and illustrative embodiments, like reference numbers are used to designate like elements. Although method embodiments may be discussed as being performed in a particular order, other method embodiments may be performed in any logical order.

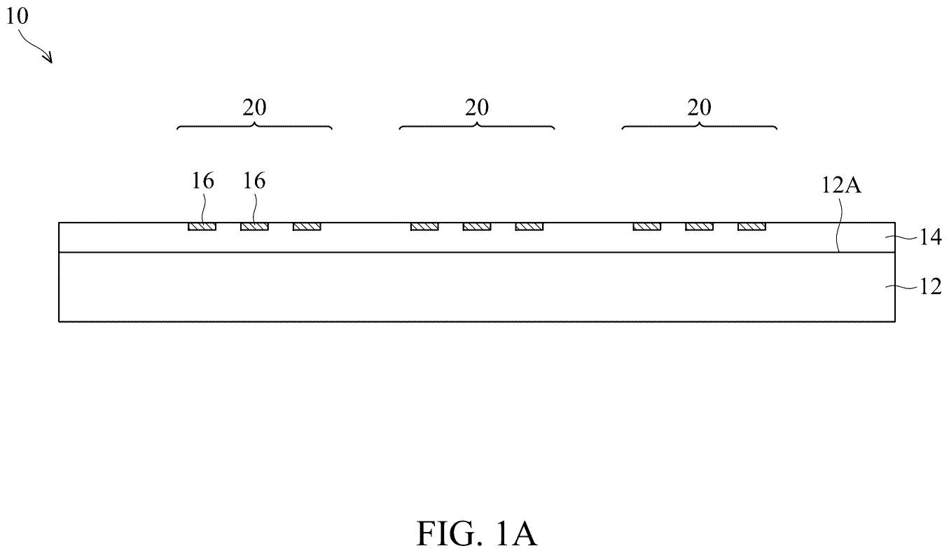

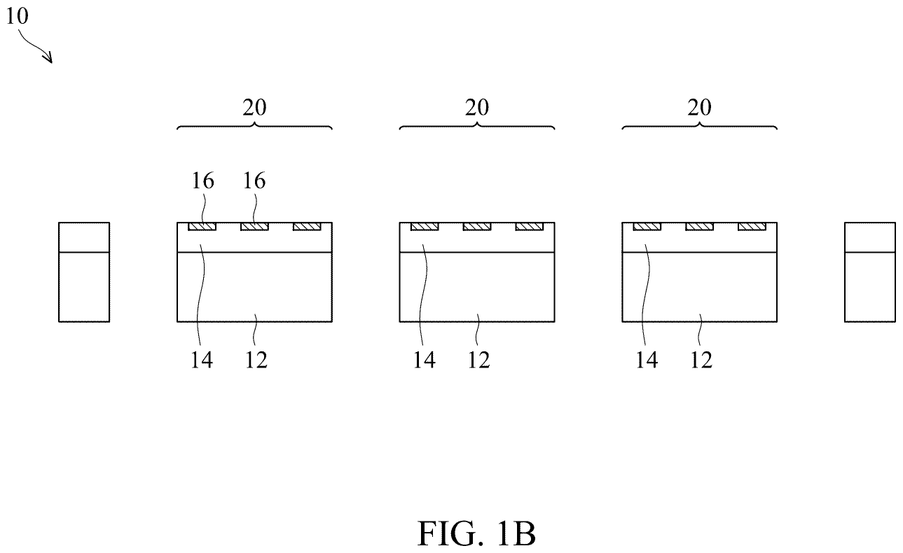

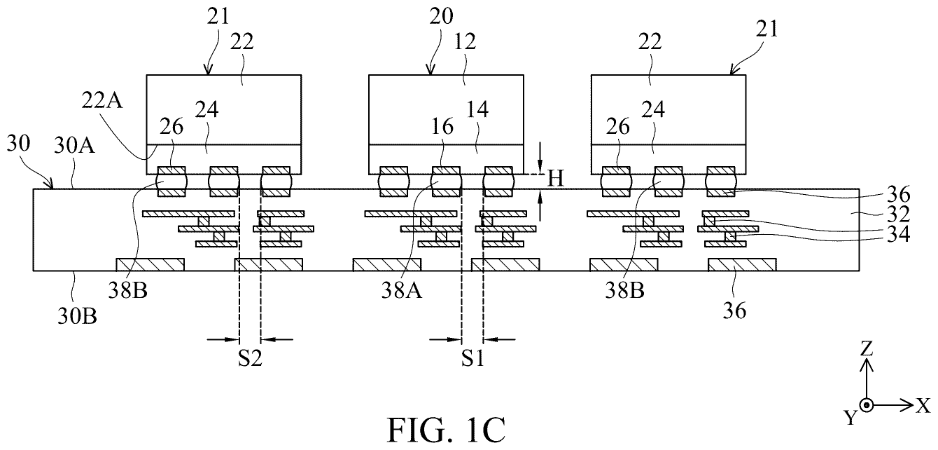

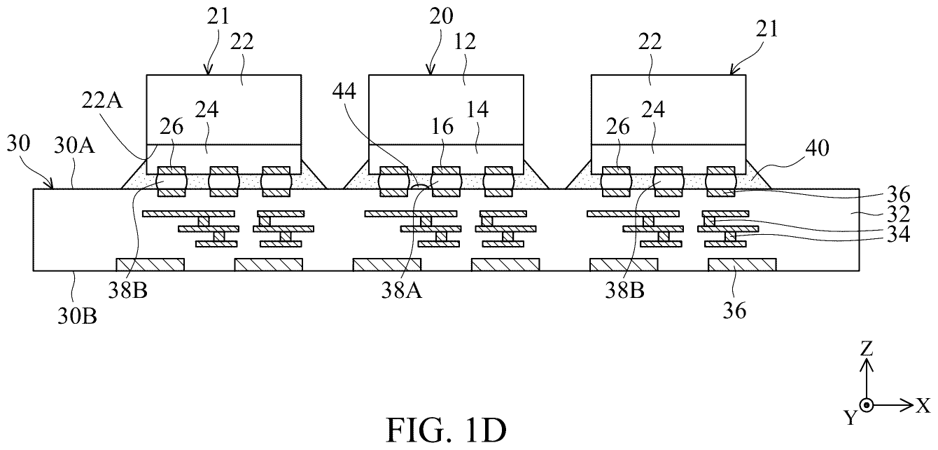

FIGS. 1A to 1D illustrate cross-sectional views of various stages in the formation of a semiconductor package (structure) 100, in accordance with some embodiments. The semiconductor package 100 described herein is a multi-chip modules (MCM) package that includes at least two different types of IC dies integrated on the same package substrate. In FIG. 1A, the formation of a wafer 10 including a plurality of package components 20 (see also FIG. 1B) is shown in accordance with some embodiments. The package components 20 may be device dies, packages, or the like.

In some embodiments, the package component 20 includes a substrate 12, which may be a bulk semiconductor substrate, a semiconductor-on-insulator (SOI) substrate, a germanium-on-insulator (GOI) substrate, or the like. The semiconductor substrate is formed of a elementary semiconductor such as silicon or germanium; a compound semiconductor such as silicon germanium, silicon carbide, gallium arsenic, gallium phosphide, indium phosphide, indium arsenide, and/or indium antimonide; an alloy semiconductor such as SiGe, GaAsP, AlInAs, AlGaAs, GaInAs, GaInP, and/or GaInAsP; or combinations thereof. Other substrates, such as multi-layered or gradient substrates, may be used. The substrate 12 may be doped or undoped. Devices (not shown) such as transistors, capacitors, resistors, diodes, or the like may be formed in and/or on the active surface 12A of the substrate 12.

In some embodiments, the package component 20 includes an interconnect structure 14, which includes one or more dielectric layer(s) and respective metallization pattern(s) formed on the active surface 12A of the substrate 12. The metallization pattern(s) in the dielectric layer(s) may route electrical signals between the devices, such as by using conductive vias and/or traces (not shown), and may also contain various electrical devices, such as capacitors, resistors, inductors, or the like. The various devices and metallization patterns may be interconnected to perform one or more functions. Conductive features 16, such as conductive pillars (for example, comprising a metal such as copper), may be formed in and/or on the interconnect structure 14 to provide an electrical connection to the external circuitry and devices. In some embodiments, the conductive features 16 protrude from the interconnect structure 14 to form pillar structures.

In some embodiments, a plurality of inter-metallization dielectric (IMD) layers may be formed in the interconnect structure 14. The IMD layers may be formed, for example, of a low-K dielectric material, such as phosphosilicate glass (PSG), borophosphosilicate glass (BPSG), fluorosilicate glass (FSG), SiOₓC_{y}, Spin-On-Glass, Spin-On-Polymers, silicon carbon material, compounds thereof, composites thereof, combinations thereof, or the like, by any suitable method known in the art, such as spinning, chemical vapor deposition (CVD), plasma-enhanced CVD (PECVD), high-density plasma chemical vapor deposition (HDP-CVD), or the like.

A metallization pattern (or one of the conductive features 16) may be formed in the respective IMD layer, for example, by using photolithography techniques to deposit and pattern a photoresist material on the IMD layer to expose portions of the IMD layer that are to become the metallization pattern. An etch process, such as an anisotropic dry etch process, may be used to create recesses and/or openings in the IMD layer corresponding to the exposed portions of the IMD layer. The recesses and/or openings may be lined with a diffusion barrier layer and filled with a conductive material. The diffusion barrier layer may comprise one or more layers of tantalum nitride, tantalum, titanium nitride, titanium, cobalt tungsten, the like, or a combination thereof, deposited by atomic layer deposition (ALD), or the like. The conductive material of the metallization patterns may comprise copper, aluminum, tungsten, silver, and combinations thereof, or the like, deposited by CVD, physical vapor deposition (PVD), or the like. Any excessive diffusion barrier layer and/or conductive material on the IMD layer may be removed, such as by using a chemical mechanical polish (CMP) process.

In FIG. 1B, after formation, the wafer 10 is singulated into individual package components 20. The package components 20 may contain the same circuitry, such as devices and metallization patterns, although they may also have different circuitry. The singulation process may be performed using blade sawing, laser dicing, or the like.

In some embodiments, each of the package components 20 (also called IC dies) includes one or more logic dies (e.g., central processing unit (CPU) dies, graphics processing unit (GPU) dies, field-programmable gate array (FPGA) dies, system-on-chip (SoC) dies, microcontroller dies, or the like), memory dies (e.g., dynamic random access memory (DRAM) dies, static random access memory (SRAM) dies, or the like), power management dies (e.g., power management integrated circuit (PMIC) dies), radio frequency (RF) dies, sensor dies, micro-electro-mechanical-system (MEMS) dies, signal processing dies (e.g., digital signal processing (DSP) dies), front-end dies (e.g., analog front-end (AFE) dies), the like, or a combination thereof.

FIGS. 1C to 1D illustrate cross-sectional views of intermediate stages in the packaging of package components (e.g., 20 and 21), which are bonded to a substrate 30. The substrate 30 may be used to provide electrical connection between semiconductor devices or dies (e.g., 20 and 21) packaged in the semiconductor package and an external electronic device (not shown). In some embodiments, the substrate 30 is a package substrate, which may be a printed circuit board (PCB), a ceramic substrate, or another suitable package substrate. In some embodiments, the substrate 30 is a cored or coreless substrate. In some embodiments, the substrate 30 may (or may not) contain devices (e.g., active devices and/or passive devices, not shown) therein or thereon.

As shown in FIG. 1C, the substrate 30 includes one or more dielectric layers 32 and conductive features 34 surrounded by the dielectric layers 32. The conductive features 34 include conductive lines providing electrical connection in horizontal directions and conductive vias providing electrical connection in vertical directions. The substrate 30 also includes contact pads 36 formed on or exposed from opposite surfaces 30A and 30B of the substrate 30 and electrically coupled to these conductive features 34. In some embodiments, the contact pads 36 at the lower surface 30B have a smaller pitch than the contact pads 36 at the upper surface 30A. In such embodiments, the substrate 30 is also referred as a fan-out redistribution substrate. The materials and formation method of the conductive features 34 and contact pads 36 of the substrate 30 may be the same or similar to those of the metallization pattern(s) and conductive features 16 of the interconnect structure 14 illustrated in FIG. 1A. In some embodiments, conductive structures (such as solder balls, not shown) may be formed on the lower surface 30B of the substrate 30 to provide an external connection.

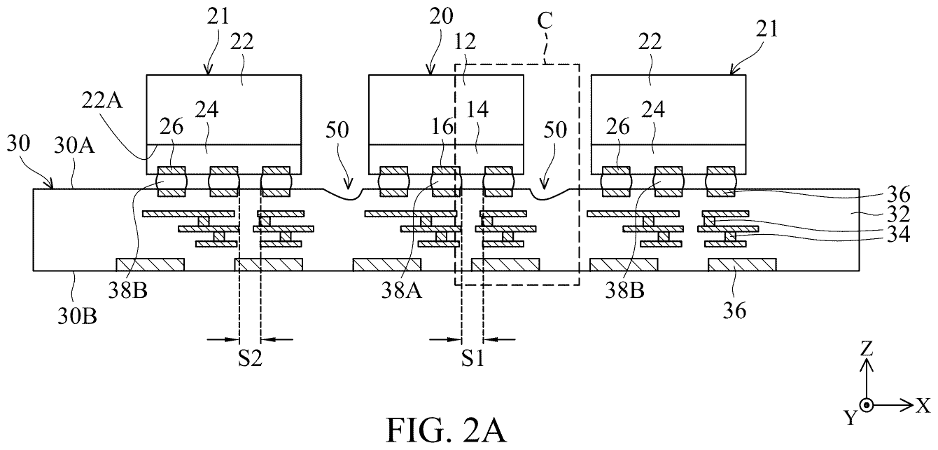

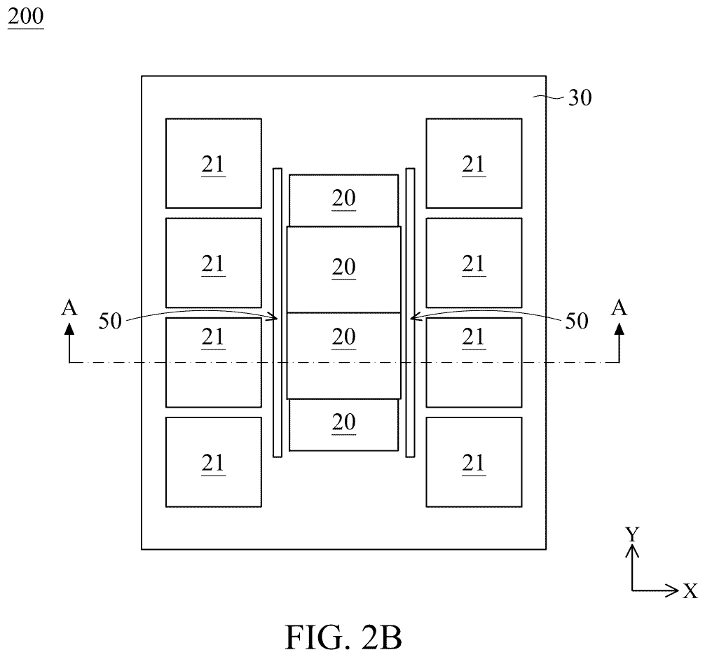

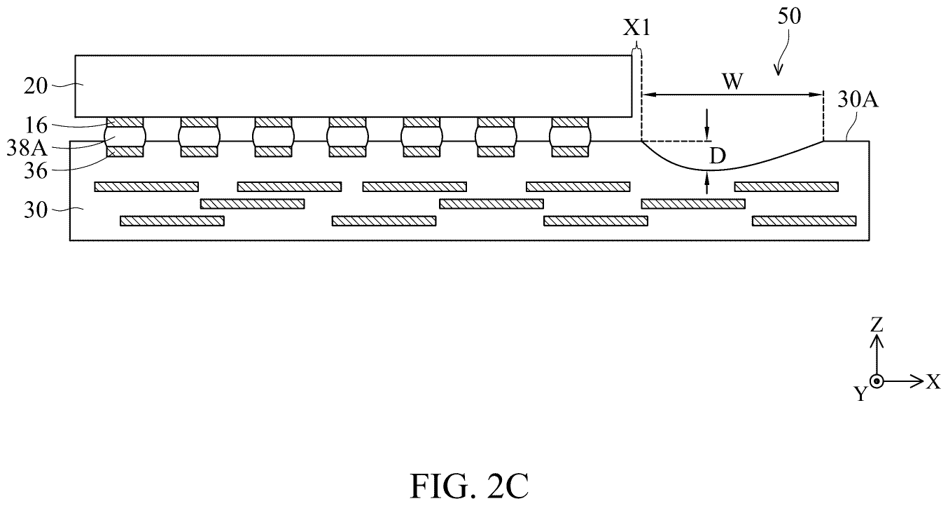

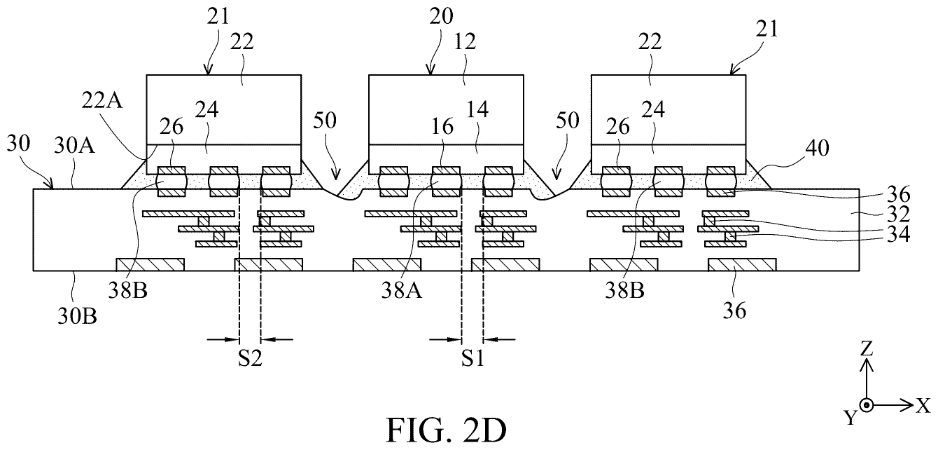

In FIG. 1C, package components 20 and 21 may be placed over the substrate 30 (e.g., the upper surface 30A) using, for example, a pick-and-place tool (not shown). In some embodiments, package components 20 and 21 may be arranged side by side over the substrate 30. For example, when viewed from the top, multiple package components 20 may be arranged in a central area of the substrate 30 (e.g., arranged in a row along the Y-direction), and multiple package components 22 may be arranged in peripheral areas of the substrate 30 (e.g., arranged in two rows along the Y-direction) near opposite sides of the substrate 30 in some cases (e.g., see FIG. 2B). Other arrangements of package components 20 and 21 may be used.

The package components 21 may be formed using processes similar to those described above with reference to the package components 20 in FIG. 1A, and may include similar structures to the package components 20, such as a substrate 22, an interconnect structure 24 formed on the active surface 22A of the substrate 22, and conductive features 26 formed in or on the interconnect structure 24 to provide an electrical connection. Thus, similar details are not repeated here.

In some embodiments, package components 20 and 21 are different types of IC dies that provide different functions. For example, the package components 20 may be processor dies (e.g., SoC dies) and the package components 21 may be memory dies (e.g., DRAM dies) in some cases. In some embodiments, each of the package components 21 includes one or more memory dies, such as a stack of memory dies (e.g., DRAM dies, SRAM dies, High-Bandwidth Memory (HBM) dies, or the like). In cases where a package component 21 includes a stack of memory dies, it can include both memory dies and a memory controller die, such as a stack of memory dies with a memory controller die. Other combinations of package components 20 and 21 may be used. In some embodiments, package components 20 and 21 may have the same or different heights in the vertical direction (e.g., Z-direction), and/or may have the same or different dimensions (e.g., surface areas) in a plane (e.g., X-Y plane) perpendicular to the vertical direction.

After placement, package components 20 and 21 may be bonded to the upper surface 30A of the substrate 30, such as by flip-chip bonding. For example, package components 20 and 21 may be bonded onto the upper surface 30A through electrical connectors 38A between each package component 20 and the substrate 30 and through electrical connectors 38B between each package component 21 and the substrate 30, as shown in FIG. 1C. In some embodiments, the bonding between the package components 20/21 and the substrate 30 may be solder bonding, and the electrical connectors 38A/38B may include solder bumps, solder balls, or the like.

In some embodiments, the electrical connectors 38A and 38B are made of a tin-containing material. The tin-containing material may include nickel, tin, tin-lead, gold, copper, silver, palladium, indium, nickel-palladium-gold, nickel-gold, the like, or a combination thereof. In some embodiments, the electrical connectors 38A and 38B are lead-free. Before the bonding process, the electrical connectors 38A/38B may be formed on the exposed conductive features 16/26 of the respective package component 20/21, the corresponding contact pads 36 of the substrate 30, or both using a plating process, such as an electroplating process. A reflow process may then be performed in order to shape the tin-containing material into the desired bump or ball shapes and physically and electrically connect the package components 20/21 to the substrate 30.

In some embodiments, before placing the electrical connectors 38A/38B on the package components 20/21 or the substrate 30, the electrical connectors 38A/38B are coated with a layer of flux (not shown) so as to prevent the electrical connectors 38A/38B from oxidizing during the subsequent bonding process. The electrical connectors 38A and 38B may be immersed in flux, or flux may be sprayed onto the electrical connectors 38A and 38B. After the bonding process, a flux cleaning process can be performed, which introduces a cleaning solvent (e.g., water or organic solvent) into the gap between the respective package components 20/21 and the substrate 30.

In FIG. 1D, after the bonding process, an underfill element 40 is dispensed into the gaps between the substrate 30 and the package components 20/21. The underfill element 40 is formed to surround and protect the electrical connectors 38A/38B beneath the respective package components 20/21, to enhance the connection between the package components 20/21 and the underlying substrate 30 and therefore the structural strength of the overall package structure. The underfill element 40 may be made of or include an insulating material such as an underfill material. The underfill material may include an epoxy, a resin, a filler material, a stress release agent (SRA), an adhesion promoter, another suitable material, or a combination thereof. In some embodiments, an underfill material in liquid state is dispensed into the gaps between the substrate 30 and the respective package components 20/21, for example, by a capillary flow process, and then cured to form the underfill element 40. After forming the underfill element 40, the semiconductor package 100 is obtained.

It should be understood that the electrical connectors 38A/38B will experience thermal stresses caused by a coefficient of thermal expansion (CTE) mismatch between the package components 20/21 and the substrate 30 during high temperature bonding, causing them to easily tear or crack. One approach to alleviate this problem is to control (e.g., reduce) the stand-off height (SoH) H (e.g., measured from the upper surface 30A of the substrate 30 to the opposing lower surface of the respective package component 20/21, as shown in FIG. 1C) of the electrical connectors 38A/38B to be less than about 50 μm during the bonding process (e.g., thermal compression bonding process). However, such a small SoH will result in smaller flux cleaning window during the flux cleaning process, resulting in flux residue and void formation in the underfill element, especially for those dies with smaller gaps between underlying conductive connectors.

For example, in cases where the package components 20 are processor dies and the package components 21 are memory dies, the density of the electrical connectors 38A below the package components 20 may be greater than the density of the electrical connectors 38B below the package components 21, and the spacing S1 between adjacent electrical connectors 38A may be smaller than the spacing S2 between adjacent electrical connectors 38B (as shown in FIG. 1C). If the SoH of the electrical connectors 38A/38B is controlled to be smaller during the bonding process as described above, it will be found that after the flux cleaning process, flux residue may exist under those package components 20 with smaller bump gaps (e.g., S1) and cause voids 44 to form in the subsequently formed underfill element 40 (as shown in FIG. 1D). Therefore, there is a need for a solution to the above problem.

FIGS. 2A to 2D illustrate various views of a semiconductor package (structure) 200, in accordance with some embodiments. The semiconductor package 200 is similar to the semiconductor package 100 described above in FIGS. 1A to 1D, except that trenches 50 are provided in the substrate 30. FIGS. 2A and 2B are cross-sectional and plan (e.g., top) views of the semiconductor package 200 before the underfill element 40 is formed, wherein FIG. 2A is a view taken along the line A-A in FIG. 2B. FIG. 2C is an enlarged view of region C shown in FIG. 2A. FIG. 2D is a cross-sectional view of the semiconductor package 200 after the underfill element 40 is formed.

In the embodiments shown in FIGS. 2A to 2D, trenches 50 are formed on the upper surface 30A of the substrate 30 (e.g., recessed from the upper surface 30A) and near the edges (i.e., sidewalls) of the package components 20 with smaller bump gaps (e.g., S1). With this configuration, the flux cleaning window can be increased through the trenches 50, thereby facilitating the flow of cleaning solvent into the gaps between the package components 20 and the substrate 30 during the flux cleaning process (i.e., improving the flux cleaning efficiency). This reduces flux residue after the flux cleaning process and prevents void formation in the subsequently formed underfill element 40. Accordingly, the reliability of the package structure is improved.

In some embodiments, trenches 50 may be formed on one or more sides of each of the package components 20. For example, in the embodiments of FIGS. 2A to 2D, trenches 50 are formed adjacent opposite sidewalls of each of the package components 20. Each of the trenches 50 may be located between the package components 20 and 21 and may extend continuously (e.g., in the Y-direction) along the sidewalls of all package components 20 on the same side in plan view. Other arrangements of the trenches 50 may be used, which will be described below.

In some embodiments, trenches 50 may be formed outside the edges (i.e., sidewalls) of each of the package components 20. That is, each of the trenches 50 does not extend below the each of the package components 20 (i.e., the trench 50 do not overlap the package component 20 in plan view), as shown in FIGS. 2B and 2C. In some embodiments, each of the trenches 50 is laterally spaced apart from the adjacent sidewall of the corresponding package component 20 by a distance X1, as shown in FIG. 2C. The distance X1 may be less than about 20 μm in some cases, although larger distances may be used as long as the trenches can facilitate the flow of cleaning solvent into the gaps between the package components 20 and the substrate 30. In alternative embodiments, the proximal end of each of the trenches 50 may be aligned vertically with the adjacent sidewall of the corresponding package component 20 (i.e., the distance X1 is equal to 0). Other arrangements of the trenches 50 may be used, which will be described below.

In some embodiments, the cross-section of each of the trenches 50 has a (smoothly) curved shape and a varying depth D (e.g., measured in the vertical direction from the bottom of the trench 50 and the upper surface 30A of the substrate 30), as shown in FIG. 2C. For example, the depth D of the trench 50 gradually increases toward the adjacent sidewall of the package component 20. In some embodiments, the (maximum) depth D of the trench 50 may be greater than about 10 μm. This facilitates the flow of cleaning solvent into the gaps between the package components 20 and the substrate 30 during the flux cleaning process. In some embodiments, the width W of each of the trenches 50 in a lateral direction perpendicular to the adjacent sidewall of the package component 20 (e.g., X-direction) may be greater than about 10 μm to achieve better drainage effect, although the present disclosure is not limited thereto. Other cross-sectional shapes of the trenches 50 may be used, which will be described below.

In some embodiments, trenches 50 may be formed in the substrate 30 prior to the bonding of package components 20 and 21. The trenches 50 may be formed using suitable photolithography and etching techniques. For example, a hard mask layer (e.g., a nitride layer, not shown) may be formed over the substrate 30 and patterned, in some embodiments. The pattern of the hard mask layer may then be transferred to the substrate 30 using one or more etching techniques, such as dry etching and/or wet etching techniques, forming the trenches 50 in the substrate 30. In some embodiments, the trenches 50 may be formed using one or more etching steps. For example, portions of each of the trenches 50 with different depth D (see FIG. 2C) may be formed in multiple etching steps. In alternative embodiments, the trenches 50 may be formed using laser ablation or other suitable removal processes.

After the trenches 50 are formed in the substrate 30, package components 20 and 21 may be bonded to the substrate 30, then a flux cleaning process may be performed, and finally an underfill element 40 (see FIG. 2D) may be dispensed into the gaps the gaps between the substrate 30 and the package components 20 and 21, as previously described in FIGS. 1C and 1D. As noted above, since no flux remains under the package components 20 and 21 after the flux cleaning process, no voids are formed in the underfill element 40. In the resulting semiconductor package (structure) 200 shown in FIG. 2D, the underfill element 40 surrounding the package components 20 may partially extend into the corresponding trenches 50.

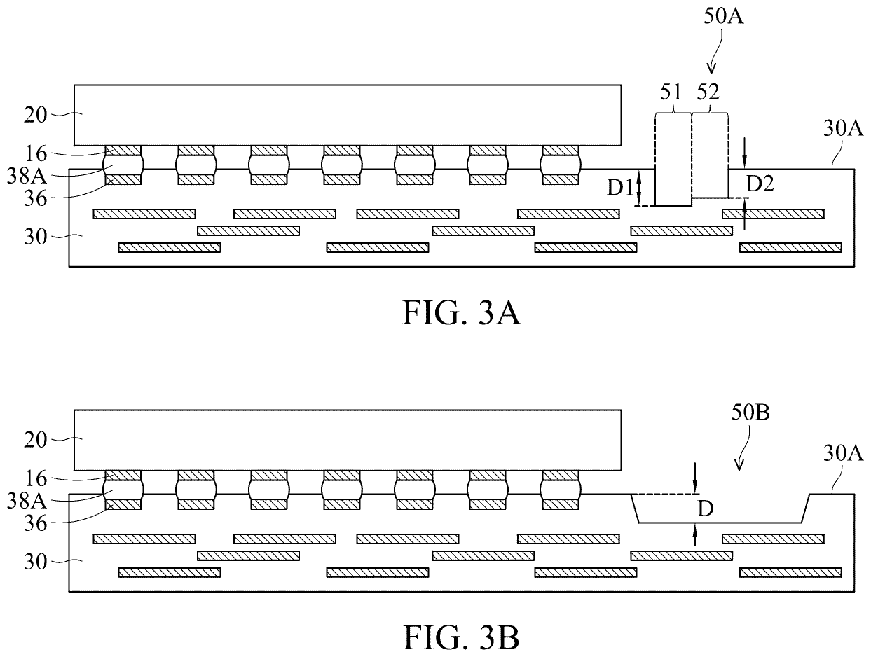

FIGS. 3A and 3B illustrate trenches (e.g., 50A, 50B) with different cross-sectional shapes in the substrate 30, in accordance with some embodiments. In FIG. 3A, the cross-section of each of the trenches 50A has a stepped shape. For example, each of the trenches 50A includes multiple portions (e.g., a first portion 51 and a second portion 52), wherein the first portion 51 is closer to the adjacent sidewall of the corresponding package component 20 than the second portion 52, and the depth D1 of the first portion 51 is greater than the depth D2 of the second portion 52. This shape of trenches 50A also facilitates the flow of cleaning solvent into the gaps between the package components 20 and the substrate 30 during the flux cleaning process. In FIG. 3B, the cross-section of each of the trenches 50B has a trapezoidal shape and a uniform depth D towards the adjacent sidewall of the package component 20. Other features (e.g., dimensions) of the trenches 50A, 50B may be similar to the trenches 50 illustrated in FIG. 2C.

It should be understood that the cross-sectional shapes of the trenches described above with reference to FIGS. 2C, 3A and 3B are only illustrative, and are not intended to be, and should not be construed to be, limiting to the present disclosure. Other suitable cross-sectional shapes may be used, such as rectangular, semicircular, triangular, etc.

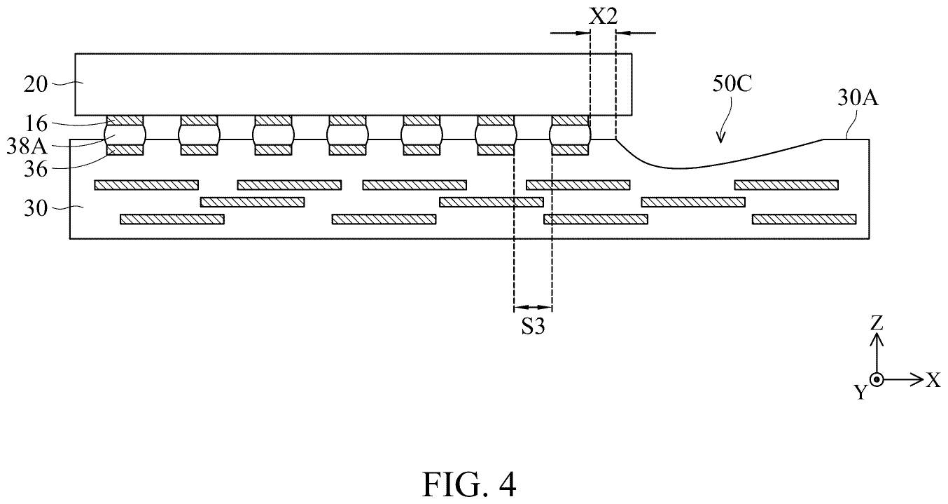

FIG. 4 illustrates trenches 50C in the substrate 30, in accordance with some embodiments. The trenches 50C differ from the trenches 50 shown in FIG. 2C in that each of the trenches 50C extends below the corresponding package component 20 (i.e., the trench 50C partially overlaps the package component 20 in plan view). Further, the proximal end of each of the trenches 50C may be laterally spaced apart from the outermost electrical connector 38A of the corresponding package component 20 by a distance X2. The distance X2 may be equal to or greater than the spacing S3 between adjacent electrical connector 38A in some cases. With this configuration, the trenches 50C can more effectively guide the flow of cleaning solvent into the gaps between the package components 20 and the substrate 30 during the flux cleaning process to improve the flux cleaning efficiency. Although not shown, each of the trenches 50C may also adopt a cross-sectional shape such as that shown in FIGS. 3A and 3B or any other suitable cross-sectional shape in different embodiments.

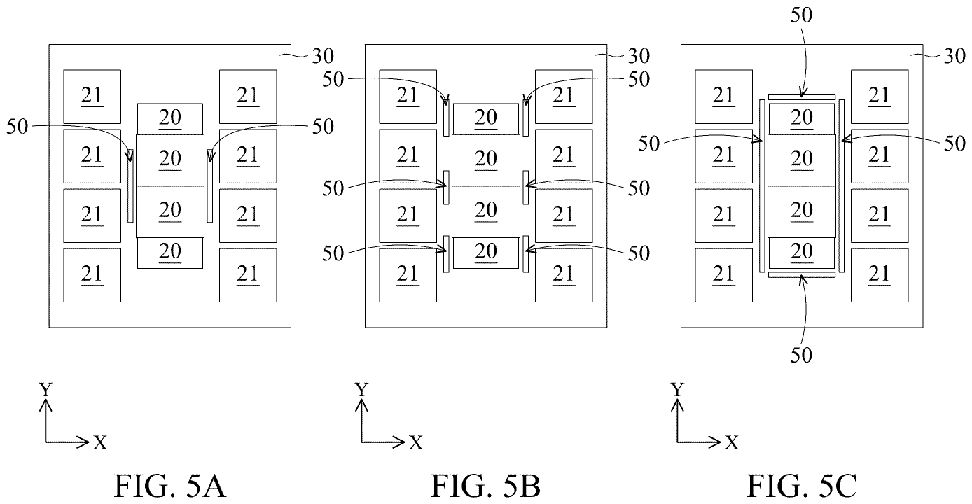

FIGS. 5A to 5C illustrate trenches 50 with different arrangements in plan view in accordance with some embodiments. In FIG. 5A, each of the trenches 50 may be located adjacent only some of the package components 20 in the inner regions of the substrate 30. In FIG. 5B, multiple trenches 50 are arranged adjacent the sidewalls of a row of package components 20 on the same side. In FIG. 5C, multiple trenches 50 are arranged along the entire perimeter of a row of package components 20, wherein some of the trenches 50 are arranged between the package components 20 and 21 (e.g., along the Y-direction), and some of the trenches 50 are arranged between the package components 20 and the edges of the substrate 30 (e.g., along the X-direction). In alternative embodiments, a single continuous rectangular frame-shaped trench can be used instead of multiple trenches.

It should be understood that the plan view arrangements of the trenches described above with reference to FIGS. 2B and 5A-5C are only illustrative, and are not intended to be, and should not be construed to be, limiting to the present disclosure. Other suitable arrangements may be used. In addition, if desired, additional trenches may be also provided near the edges of the package components 21 (e.g., with larger bump gaps) to improve the flux cleaning efficiency, in different embodiments.

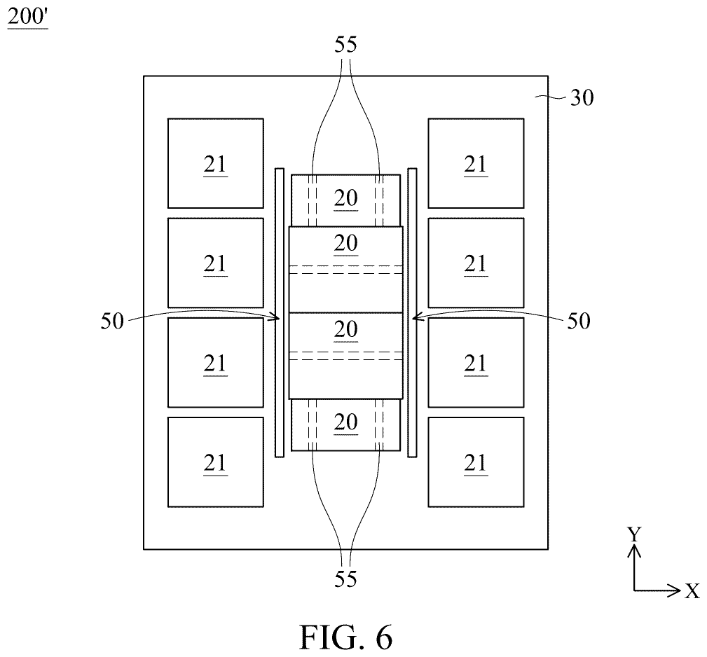

FIG. 6 illustrates a plan view of a semiconductor package 200′, in accordance with some embodiments. The semiconductor package 200′ is similar to the semiconductor package 200 described above in FIGS. 2A to 2D, except that additional trenches 55 are provided in the substrate 30 and extend beneath the package components 20 (e.g., located between adjacent electrical connectors 38A of each package component 20 (not shown)). The additional trenches 55 may have a similar cross-sectional shape to the trenches (e.g., 50, 50A, 50B) described above with reference to FIGS. 2C and 3A-3B. As shown in FIG. 6, each of the additional trenches 55 may extend from one side of a package component 20 to the opposite side in plan view. The extension direction of the additional trenches 55 may be the same as or different from the extension direction of the trenches 50 around the package components 20. In some embodiments, some of the additional trenches 55 may (or may not) be connected to the trenches 50. With this configuration, the additional trenches 55 also facilitate the flow of cleaning solvent in the gaps between the package components 20 and the substrate 30 during the flux cleaning process.

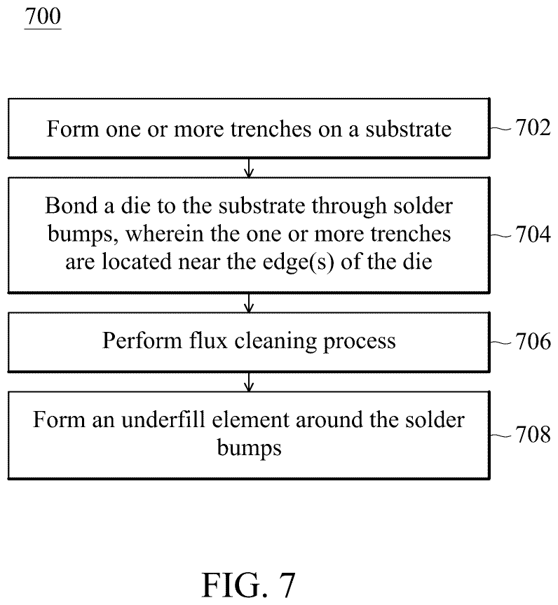

FIG. 7 illustrates a process flow 700 for forming a semiconductor package (e.g., 200 or 200′), in accordance with some embodiments. Process flow 700 includes operation 702 in which one or more trenches (e.g., 50, 50A, 50B, 50C) are formed on a substrate. Process flow 700 also includes operation 704 in which a die (e.g., 20) is bonded to the substrate through solder bumps (e.g., 38A), wherein the one or more trenches are located near the edge(s) of the die. Process flow 700 also includes operation 706 in which a flux cleaning flux is performed. Process flow 700 also includes operation 708 in which an underfill element (e.g., 40) is formed around the solder bumps.

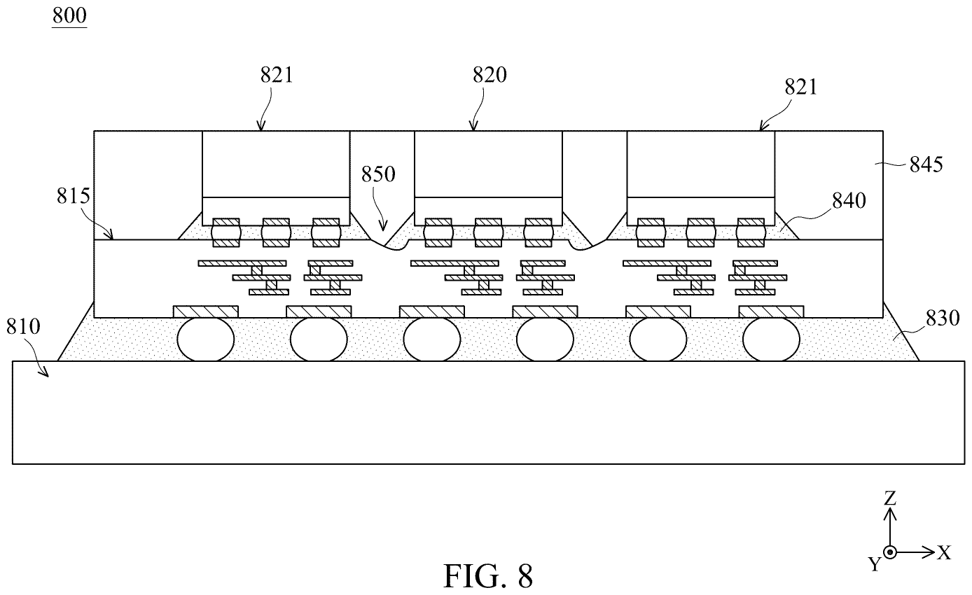

FIG. 8 illustrates a cross-sectional view of a semiconductor package (structure) 800, in accordance with some embodiments. The semiconductor package 800 is a chip-on-wafer-on-substrate (CoWoS) package that includes a package substrate 810, an interposer substrate 815 (e.g., silicon or organic interposer substrate) bonded over the package substrate 810, and package components 820, 821 (e.g., IC dies, which are similar to the above-mentioned package components 20, 21) bonded over the interposer substrate 815. Further, the semiconductor package 800 may also include an underfill element 830 disposed around the electrical connectors between the package substrate 810 and the interposer substrate 815, an underfill element 840 disposed around the electrical connectors between the respective package components 820/821 and the interposer substrate 815, and a molding layer 845 encapsulating the package components 820, 821. Further known details about the CoWoS package are not described here.

In the semiconductor package 800, one or more trenches 850 may also be provided in the interposer substrate 815 (e.g., the surface facing the package components 820, 821) and near the edge(s) of the package components 820 (e.g., with smaller bump gaps) so as to facilitate the flow of cleaning solvent into the gaps between the package components 820 and the interposer substrate 815 during flux cleaning, similar to the embodiments described above. This reduces flux residue and prevents void formation in the underfill element (e.g., 840), thereby increasing the reliability of the package structure. The structure, configuration, and formation method of the trenches 850 may be similar to the structure, configuration, and formation method of the trenches (e.g., 50, 50A, 50B, 50C) as previously described, so similar details are not repeated here.

It should be understood that the structures, configurations and the manufacturing methods described herein are only illustrative, and are not intended to be, and should not be construed to be, limiting to the present disclosure. Many alternatives and modifications will be apparent to those skilled in the art, once informed by the present disclosure. For example, various features in the above-mentioned different embodiments can be combined arbitrarily.

In summary, the embodiments of the present disclosure have some advantageous features. By forming one or more trenches in the substrate and near the edge(s) of a semiconductor die thereon, the flux cleaning window can be increased. This facilitates the flow of cleaning solvent into the gaps between the die and the substrate during flux cleaning, thereby reducing flux residue and preventing void formation in the subsequently formed underfill element. As a result, the reliability of the package structure is improved.

In accordance with some embodiments, a semiconductor package structure is provided. The semiconductor package structure includes a substrate. An integrated circuit (IC) die is bonded to the surface of the substrate through electrical connectors. A trench is formed on the surface of the substrate and near a sidewall of the IC die.

In accordance with some embodiments, a semiconductor package structure is provided. The semiconductor package structure includes a substrate. A first integrated circuit (IC) die is bonded to the surface of the substrate through first electrical connectors, wherein there is a first spacing between adjacent first electrical connectors. A second IC die is bonded to the surface of the substrate through second electrical connectors, wherein there is a second spacing between adjacent second electrical connectors, and the first spacing is smaller than the second spacing. A first trench is formed on the surface of the substrate, wherein the first trench is closer to the first IC die and farther from the second IC die in a plan view.

In accordance with some embodiments, a method of forming a semiconductor package structure is provided. The method includes forming at least one trench on a substrate. The method also includes bonding an integrated circuit (IC) die to the substrate through solder bumps, wherein said trench is located near at least one edge of the IC die. The method also includes performing a flux cleaning process to introduce a cleaning solvent into the gap between the IC die and the substrate. The method also includes forming an underfill element around the solder bumps.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a substrate;
an integrated circuit (IC) die bonded to a surface of the substrate through electrical connectors; and
a trench formed on the surface of the substrate and near a sidewall of the IC die.

2. The semiconductor package structure as claimed in claim 1, wherein the trench is located outside the sidewall of the IC die in a plan view.

3. The semiconductor package structure as claimed in claim 2, wherein a proximal end of the trench is aligned vertically with the sidewall of the IC die.

4. The semiconductor package structure as claimed in claim 1, wherein the trench extends below the IC die such that a portion of the trench overlaps the IC die in a plan view.

5. The semiconductor package structure as claimed in claim 4, wherein a proximal end of the trench is laterally spaced apart from an outermost electrical connector of the electrical connectors.

6. The semiconductor package structure as claimed in claim 1, wherein a depth of the trench gradually increases toward the sidewall of the IC die.

7. The semiconductor package structure as claimed in claim 6, wherein a cross-section of the trench has a curved shape.

8. The semiconductor package structure as claimed in claim 6, wherein a cross-section of the trench has a stepped shape.

9. The semiconductor package structure as claimed in claim 1, wherein the trench has a uniform depth toward the sidewall of the IC die.

10. The semiconductor package structure as claimed in claim 1, further comprising:
an underfill element disposed around the electrical connectors, wherein the underfill element partially extends into the trench.

11. A semiconductor package structure, comprising:
a substrate;
a first integrated circuit (IC) die bonded to a surface of the substrate through first electrical connectors, wherein the first electrical connectors have a first spacing between adjacent first electrical connectors;
a second IC die bonded to the surface of the substrate through second electrical connectors, wherein the second electrical connectors have a second spacing between adjacent second electrical connectors, and the first spacing is smaller than the second spacing; and
a first trench formed on the surface of the substrate, wherein the first trench is closer to the first IC die and farther from the second IC die in a plan view.

12. The semiconductor package structure as claimed in claim 11, wherein the first trench extends below the first IC die.

13. The semiconductor package structure as claimed in claim 11, wherein the first trench is located near a first sidewall of the first IC die, and
wherein the semiconductor package further comprises a second trench formed on the surface of the substrate and located near a second sidewall that is different from the first sidewall.

14. The semiconductor package structure as claimed in claim 11, further comprising:
a second trench formed on the surface of the substrate and located beneath the first IC die.

15. The semiconductor package structure as claimed in claim 14, wherein the second trench extends from a side of the first IC die to an opposite side of the first IC die in the plan view.

16. The semiconductor package structure as claimed in claim 15, wherein an extension direction of the second trench is different from an extension direction of the first trench.

17. A method of forming a semiconductor package structure, comprising:
forming at least one trench on a substrate;
bonding an integrated circuit (IC) die to the substrate through solder bumps, wherein the at least one trench is located near at least one edge of the IC die;
performing a flux cleaning process to introduce a cleaning solvent into a gap between the IC die and the substrate; and
forming an underfill element around the solder bumps.

18. The method as claimed in claim 17, wherein the at least one trench is formed using an etching process or a laser ablation process.

19. The method as claimed in claim 17, wherein a depth of the at least one trench is greater than 10 μm.

20. The method as claimed in claim 17, wherein the substrate comprises a package substrate or an interposer substrate.
